(19) United States
(12) Patent Application Publication
(10) Pub. No.: US 2024/0186121 A1
(43) Pub. Date: Jun. 6, 2024

(54) THERMAL CHOKE PLATE

(71) Applicant: Applied Materials, Inc., Santa Clara, CA (US)

(72) Inventors: Vellaichamy Nagappan, Ramanathapuram (IN); Viren Kalsekar, Mountain View, CA (US); Jeongmin Lee, San Ramon, CA (US); Vinay K. Prabhakar, Fremont, CA (US); Pratap Chandran, Bengaluru (IN); Dharma Ratnam Srichurnam, Hyderabad (IN); Azhar Khan, Dewas (IN); Sumit Subhash Singh, Mumbai (IN); Siva Chandrasekar, Hosur (IN); Satish Radhakrishnan, San Jose, CA (US)

(73) Assignee: Applied Materials, Inc., Santa Clara, CA (US)

(21) Appl. No.: 18/076,234

(22) Filed: Dec. 6, 2022

(51) Int. Cl. H01J 37/32; H01L 21/687

(52) U.S. Cl. CPC H01J 37/32633; H01J 37/32724; H01L 21/68785

(57) ABSTRACT

Exemplary choke plates for use in a substrate processing system may include a plate defining a first aperture through the plate and a second aperture through the plate. The second aperture may be laterally offset from the first aperture. The plate may include a flange that defines a purging inlet. The plate may include a rim defining a plurality of purging outlets that are fluidly coupled with the purging inlet. Each of the plurality of purging outlets may be fluidly coupled with the first aperture.

### TECHNICAL FIELD

The present technology relates to semiconductor processing equipment. More specifically, the present technology relates to semiconductor chamber components and methods of substrate processing.

### BACKGROUND

Temperature non-uniformity across the substrate during substrate processing can lead to uneven and inconsistent substrates. Such non-uniformity may arise when a faceplate opposite a pedestal supporting the substrate undergoes sublimation along its face. This sublimation can lead to temperature non-uniformity across the substrate during processing. In order to avoid this sublimation, it would be beneficial to ensure that the faceplate is properly purged during substrate processing. However, the flow rate required to purge the faceplate with traditional substrate processing system designs are not enough to prevent faceplate sublimation.

As such, it would be beneficial to optimize the semiconductor processing equipment to purge a substrate processing region at a large height.

Additionally, contaminants within semiconductor substrates can adversely affect the performance and quality of the substrate. As such, substrate processing environments are directed to minimizing the risk of contaminants entering the substrates during processing, which may arise from the components of the semiconductor processing equipment itself. For example, stainless steel components can react with purge gases, such as nitrogen trifluoride, to form metal contaminants during corrosion that may invade the substrates during processing. While these stainless steel components may be given a coating to help shield the stainless steel material from reacting to the purge gases, at high enough temperatures (e.g., the temperatures at which substrates are processed, such as 400° C.), such coating can flake off and leave the stainless steel material exposed for oxidation and corrosion. Such heat can additionally exacerbate this issue by increasing the rate of oxidation and corrosion of the exposed stainless steel components, thus further increasing the risk that contaminants enter the substrate processing environment.

As such, it would be additionally beneficial to minimize the risk of stainless steel components within substrate processing environments from reacting with purge gases to form contaminants.

### SUMMARY

Exemplary choke plates for use in a substrate processing system may include a plate defining a first aperture through the plate and a second aperture through the plate. The second aperture may be laterally offset from the first aperture. The plate may include a flange that defines a purging inlet. The plate may include a rim defining a plurality of purging outlets that are fluidly coupled with the purging inlet. Each of the plurality of purging outlets may be fluidly coupled with the first aperture.

In some embodiments, the purging inlet may be defined along a top surface of the flange. The purging inlet may be defined along a bottom surface of the flange. The rim may at least partially define a first plenum, a second plenum, and at least one baffle that extends between and fluidly couples the first and second plenum. The first and second plenum and baffle may be in fluid communication with the purging inlet and the plurality of purging outlets. The at least one baffle may include a plurality of baffles. The plurality of baffles may include a first baffle and a second baffle. The first baffle may have a different cross-sectional area than the second baffle. The first baffle may be closer to the purging inlet than the second baffle. The first baffle may have a smaller cross-sectional area than the second baffle. The choke plate may include a closing plate. The closing plate may be engaged to the rim to define the first and second plenums and the baffle therebetween.

Some embodiments of the present technology may encompass substrate processing systems. The systems may include a chamber body defining a transfer region. The systems may include a substrate support disposed within the transfer region. The systems may include a lid plate seated on the chamber body. The lid plate may define an aperture through the lid plate. The systems may include a choke plate seated on the lid plate along a first surface of the choke plate. The choke plate may define a first aperture through the plate and a second aperture through the plate. The second aperture may be laterally offset from the first aperture. The choke plate may include a flange that defines a purging inlet. The choke plate may include a rim defining a plurality of purging outlets that are fluidly coupled with the purging inlet. Each of the plurality of purging outlets may be fluidly coupled with the first aperture. The systems may include a pumping liner seated on the choke plate. The systems may include a faceplate seated on the pumping liner.

In some embodiments, the chamber body may define a channel in communication with the purging inlet to form a part of a processing purge flow path. The systems may include a bellow coupled with an underside of the substrate support. The bellow may include a flange having an RF gasket disposed thereon that is aligned along a vertical axis with the rim of the choke plate. The substrate support may be vertically translatable within the transfer region between a transfer position and a processing position. In the processing position the bellow may be expanded and the RF gasket may contact the rim of the choke plate to close an RF return path. In the transfer position the bellow may be contracted and the RF gasket may be vertically spaced apart from the rim of the choke plate. The rim of the choke plate may have a length of between about 70 mm and 100 mm.

Some embodiments of the present technology may encompass substrate processing systems that may include a chamber body defining a transfer region. The systems may include a substrate support disposed within the transfer region. The substrate support may include a ground plate. The substrate support may include a first isolator seated atop the ground plate. The substrate support may include a second isolator seated atop the first isolator.

The top isolator may define a first set of dimples extending from a surface of the first isolator and the second isolator may define a second set of dimples extending from a surface of the second isolator. A height of each of the first set of dimples and the second set of dimples may be equal. A height of each of the first set of dimples may be different than a height of the second set of dimples. The surface of the first isolator may be a top surface and the first set of dimples may extend from the top surface. The surface of the second isolator may be a bottom surface and the second set of dimples may extend from the bottom surface. The first isolator may define a third set of dimples extending from a bottom surface of the first isolator. The systems may include an outer isolator seated on at least a portion of the first isolator. The top isolator may define a ledge. The outer isolator may include a flange seated atop the ledge.

### BRIEF DESCRIPTION OF THE DRAWINGS

A further understanding of the nature and advantages of the disclosed technology may be realized by reference to the remaining portions of the specification and the drawings.

FIG. 1A shows a schematic top view of an exemplary processing tool according to some embodiments of the present technology.

FIG. 1B shows a schematic partial cross-sectional view of an exemplary processing system according to some embodiments of the present technology.

FIG. 2 shows a schematic isometric view of a transfer section of an exemplary substrate processing system according to some embodiments of the present technology.

FIG. 3 shows a cross-sectional view of an exemplary system arrangement of an exemplary substrate processing system according to some embodiments of the present technology.

FIG. 4 shows a top isometric view of a choke plate of the substrate processing system of FIG. 3.

FIG. 5 shows a bottom isometric view of a choke plate of the substrate processing system of FIG. 3.

FIG. 6 shows a cross-sectional view along section view A-A of the choke plate of FIG. 4.

FIG. 7 shows a cross-sectional view along section view B-B of the choke plate of FIG. 4.

FIG. 8 shows a cross-sectional view along section view C-C of the choke plate of FIG. 4.

FIG. 9 shows a partial cross-sectional view of an exemplary system arrangement of an exemplary substrate processing system according to some embodiments of the present technology.

FIG. 10 shows a top isometric view of the isolators and various components of the substrate processing system of FIG. 3.

FIG. 11 shows a cross-sectional view of the isolators and various components of the substrate processing system of FIG. 10.

FIG. 12 shows a top isometric view of a bellow according to some embodiments of the present technology.

FIG. 13 shows a side elevation view of the bellow of FIG. 12.

FIG. 14 shows a partial cross-sectional view of a bellow in a processing chamber according to some embodiments of the present technology.

FIG. 15 shows a partial cross-sectional view of a bellow in a processing chamber according to some embodiments of the present technology.

FIG. 16 shows a partial cross-sectional view of a bellow in a processing chamber according to some embodiments of the present technology.

FIG. 17 shows a partial cross-sectional view of a bellow in a processing chamber according to some embodiments of the present technology.

### DETAILED DESCRIPTION

Substrate processing can include time-intensive operations for adding, removing, or otherwise modifying materials on a wafer or semiconductor substrate. Efficient movement of the substrate may reduce queue times and improve substrate throughput. To improve the number of substrates processed within a cluster tool, additional chambers may be incorporated onto the mainframe. Although transfer robots and processing chambers can be continually added by lengthening the tool, this may become space inefficient as the footprint of the cluster tool scales. Accordingly, the present technology may include cluster tools with an increased number of processing chambers within a defined footprint. To accommodate the limited footprint about transfer robots, the present technology may increase the number of processing chambers laterally outward from the robot. For example, some conventional cluster tools may include one or two processing chambers positioned about sections of a centrally located transfer robot to maximize the number of chambers radially about the robot. The present technology may expand on this concept by incorporating additional chambers laterally outward as another row or group of chambers. For example, the present technology may be applied with cluster tools including three, four, five, six, or more processing chambers accessible at each of one or more robot access positions.

However, as additional process locations are added, accessing these locations from a central robot may no longer be feasible without additional transfer capabilities at each location. Some conventional technologies may include wafer carriers on which the substrates remain seated during transition. However, wafer carriers may contribute to thermal non-uniformity and particle contamination on substrates. The present technology overcomes these issues by incorporating a transfer section vertically aligned with processing chamber regions and a carousel or transfer apparatus that may operate in concert with a central robot to access additional wafer positions.

Additionally, conventional faceplates may experience sublimation of that may lead to temperature uniformity issues across the faceplate. To alleviate these issues conventional systems incorporate purge gas that is introduced into the chamber from a bottom of the chamber. However, such purge gas designs suffer from several drawbacks. For example, the bottom purge may introduce metal contamination on wafer as the purge gas may break off oxidized portions of stainless steel chamber components including a grounding plate at the bottom of the pedestal). Additionally, in multi-chamber systems that share a single transfer volume (but that have separate process/reaction volumes for each chamber) the introduction of purge gas from the bottom of the chamber (e.g., within the shared transfer volume) may cause large temperature differences between the transfer volume and reactor volume. Conventional chambers may also have small diffusion volumes, which may require higher flow rates of purge gas to adequately purge the chamber.

The present technology addresses these issues by providing thermal choke plates that introduce a purge gas into the chamber within the reaction volume. This may help reduce the pressure delta between the reaction volume and transfer volume, as well as reduce the volume of purge gas needed to purge the chamber. The introduction of purge gas within the reaction volume may also improve the temperature uniformity during hot-leveling of the pedestal. The choke plate height may also be increased, which may provide a longer and more uniform diffusion surface alongside the pedestal, and may help prevent the sublimation of the faceplate. Embodiments may utilize a multi-piece isolator to help thermally isolate the ground plate from high temperatures of the pedestal proximate the substrate support surface.

Although the remaining disclosure will routinely identify specific structures, such as four-position transfer regions, for which the present structures and methods may be employed, it will be readily understood that the systems and methods are equally applicable to any number of structures and devices that may benefit from the transfer capabilities explained. Accordingly, the technology should not be considered to be so limited as for use with any particular structures alone. Moreover, although an exemplary tool system will be described to provide foundation for the present technology, it is to be understood that the present technology can be incorporated with any number of semiconductor processing chambers and tools that may benefit from some or all of the operations and systems to be described.

Although the remaining disclosure will routinely identify specific structures, such as four-position transfer regions, for which the present structures and methods may be employed, it will be readily understood that the faceplates or components discussed may be equally employed in any number of other systems or chambers, as well as any other apparatus in which multiple components may be joined or coupled. Accordingly, the technology should not be considered to be so limited as for use with any particular chambers alone. Moreover, although an exemplary tool system will be described to provide foundation for the present technology, it is to be understood that the present technology can be incorporated with any number of semiconductor processing chambers and tools that may benefit from some or all of the operations and systems to be described.

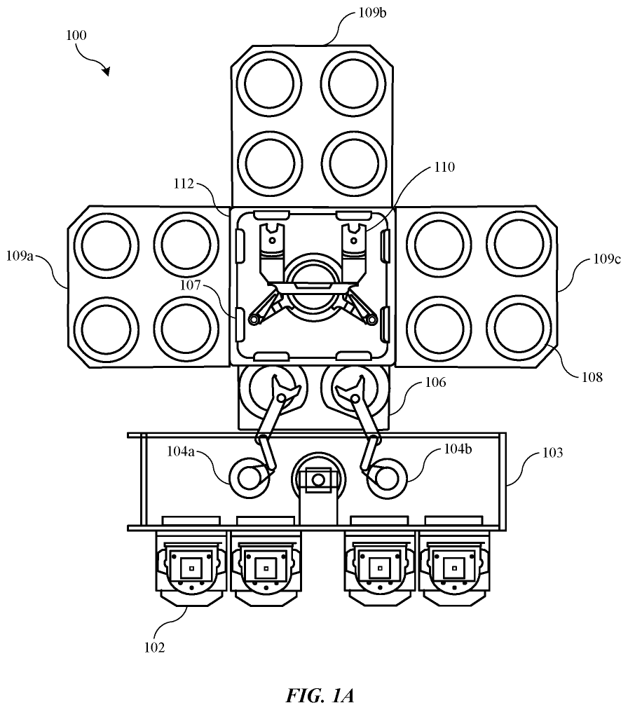

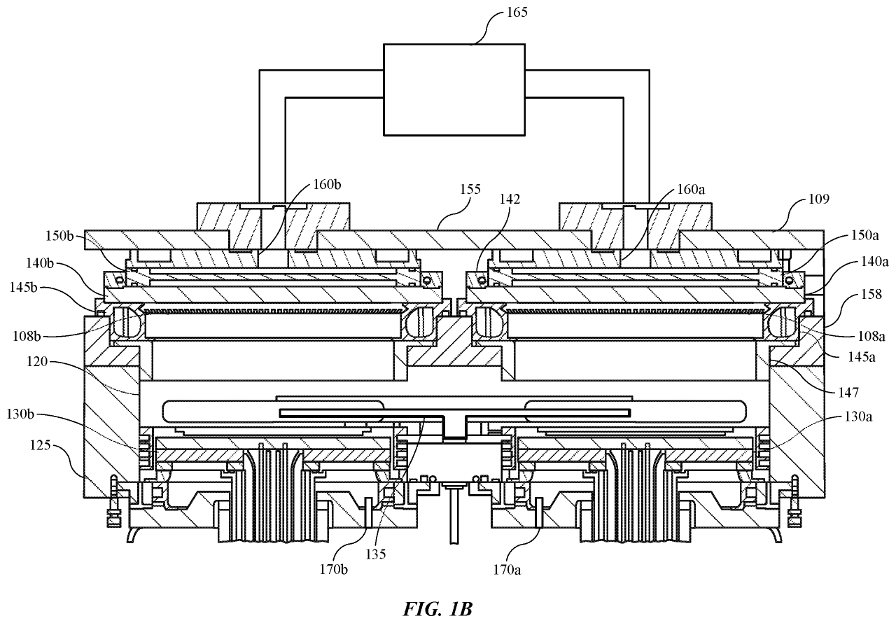

FIG. 1A shows a top plan view of one embodiment of a substrate processing tool or processing system 100 of deposition, etching, baking, and curing chambers according to some embodiments of the present technology. In the figure, a set of front-opening unified pods 102 supply substrates of a variety of sizes that are received within a factory interface 103 by robotic arms 104a and 104b and placed into a load lock or low pressure holding area 106 before being delivered to one of the substrate processing regions 108, positioned in chamber systems or quad sections 109a-c, which may each be a substrate processing system having a transfer region fluidly coupled with a plurality of processing regions 108. Although a quad system is illustrated, it is to be understood that platforms incorporating standalone chambers, twin chambers, and other multiple chamber systems are equally encompassed by the present technology. A second robotic arm 110 housed in a transfer chamber 112 may be used to transport the substrate wafers from the holding area 106 to the quad sections 109 and back, and second robotic arm 110 may be housed in a transfer chamber with which each of the quad sections or processing systems may be connected. Each substrate processing region 108 can be outfitted to perform a number of substrate processing operations including any number of deposition processes including cyclical layer deposition, atomic layer deposition, chemical vapor deposition, physical vapor deposition, as well as etch, pre-clean, anneal, plasma processing, degas, orientation, and other substrate processes.

Each quad section 109 may include a transfer region that may receive substrates from, and deliver substrates to, second robotic arm 110. The transfer region of the chamber system may be aligned with the transfer chamber having the second robotic arm 110. In some embodiments the transfer region may be laterally accessible to the robot. In subsequent operations, components of the transfer sections may vertically translate the substrates into the overlying processing regions 108. Similarly, the transfer regions may also be operable to rotate substrates between positions within each transfer region. The substrate processing regions 108 may include any number of system components for depositing, annealing, curing and/or etching a material film on the substrate or wafer. In one configuration, two sets of the processing regions, such as the processing regions in quad section 109a and 109b, may be used to deposit material on the substrate, and the third set of processing chambers, such as the processing chambers or regions in quad section 109c, may be used to cure, anneal, or treat the deposited films. In another configuration, all three sets of chambers, such as all twelve chambers illustrated, may be configured to both deposit and/or cure a film on the substrate.

As illustrated in the figure, second robotic arm 110 may include two arms for delivering and/or retrieving multiple substrates simultaneously. For example, each quad section 109 may include two accesses 107 along a surface of a housing of the transfer region, which may be laterally aligned with the second robotic arm. The accesses may be defined along a surface adjacent the transfer chamber 112. In some embodiments, such as illustrated, the first access may be aligned with a first substrate support of the plurality of substrate supports of a quad section. Additionally, the second access may be aligned with a second substrate support of the plurality of substrate supports of the quad section. The first substrate support may be adjacent to the second substrate support, and the two substrate supports may define a first row of substrate supports in some embodiments. As shown in the illustrated configuration, a second row of substrate supports may be positioned behind the first row of substrate supports laterally outward from the transfer chamber 112. The two arms of the second robotic arm 110 may be spaced to allow the two arms to simultaneously enter a quad section or chamber system to deliver or retrieve one or two substrates to substrate supports within the transfer region.

Any one or more of the transfer regions described may be incorporated with additional chambers separated from the fabrication system shown in different embodiments. It will be appreciated that additional configurations of deposition, etching, annealing, and curing chambers for material films are contemplated by processing system 100. Additionally, any number of other processing systems may be utilized with the present technology, which may incorporate transfer systems for performing any of the specific operations, such as the substrate movement. In some embodiments, processing systems that may provide access to multiple processing chamber regions while maintaining a vacuum environment in various sections, such as the noted holding and transfer areas, may allow operations to be performed in multiple chambers while maintaining a particular vacuum environment between discrete processes.

FIG. 1B shows a schematic cross-sectional elevation view of one embodiment of an exemplary processing tool, such as through a chamber system, according to some embodiments of the present technology. FIG. 1B may illustrate a cross-sectional view through any two adjacent processing regions 108 in any quad section 109. The elevation view may illustrate the configuration or fluid coupling of one or more processing regions 108 with a transfer region 120. For example, a continuous transfer region 120 may be defined by a transfer region housing 125. The housing may define an open interior volume in which a number of substrate supports 130 may be disposed. For example, as illustrated in FIG. 1A, exemplary processing systems may include four or more, including a plurality of substrate supports 130 distributed within the housing about the transfer region. The substrate supports may be pedestals as illustrated, although a number of other configurations may also be used. In some embodiments the pedestals may be vertically translatable between the transfer region 120 and the processing regions overlying the transfer region. The substrate supports may be vertically translatable along a central axis of the substrate support along a path between a first position and a second position within the chamber system. Accordingly, in some embodiments each substrate support 130 may be axially aligned with an overlying processing region 108 defined by one or more chamber components.

The open transfer region may afford the ability of a transfer apparatus 135, such as a carousel, to engage and move substrates, such as rotationally, between the various substrate supports. The transfer apparatus 135 may be rotatable about a central axis. This may allow substrates to be positioned for processing within any of the processing regions 108 within the processing system. The transfer apparatus 135 may include one or more end effectors that may engage substrates from above, below, or may engage exterior edges of the substrates for movement about the substrate supports. The transfer apparatus may receive substrates from a transfer chamber robot, such as robot 110 described previously. The transfer apparatus may then rotate substrates to alternate substrate supports to facilitate delivery of additional substrates.

Once positioned and awaiting processing, the transfer apparatus may position the end effectors or arms between substrate supports, which may allow the substrate supports to be raised past the transfer apparatus 135 and deliver the substrates into the processing regions 108, which may be vertically offset from the transfer region. For example, and as illustrated, substrate support 130a may deliver a substrate into processing region 108a, while substrate support 130b may deliver a substrate into processing region 108b. This may occur with the other two substrate supports and processing regions, as well as with additional substrate supports and processing regions in embodiments for which additional processing regions are included. In this configuration, the substrate supports may at least partially define a processing region 108 from below when operationally engaged for processing substrates, such as in the second position, and the processing regions may be axially aligned with an associated substrate support. The processing regions may be defined from above by a faceplate 140, as well as other lid stack components. In some embodiments, each processing region may have individual lid stack components, although in some embodiments components may accommodate multiple processing regions 108. Based on this configuration, in some embodiments each processing region 108 may be fluidly coupled with the transfer region, while being fluidly isolated from above from each other processing region within the chamber system or quad section.

In some embodiments the faceplate 140 may operate as an electrode of the system for producing a local plasma within the processing region 108. As illustrated, each processing region may utilize or incorporate a separate faceplate. For example, faceplate 140a may be included to define from above processing region 108a, and faceplate 140b may be included to define from above processing region 108b. In some embodiments the substrate support may operate as the companion electrode for generating a capacitively-coupled plasma between the faceplate and the substrate support. The faceplate may be heated in some embodiments with a heater 142 extending about the faceplate. A pumping liner 145 may at least partially define the processing region 108 radially, or laterally depending on the volume geometry. Again, separate pumping liners may be utilized for each processing region. For example, pumping liner 145a may at least partially radially define processing region 108a, and pumping liner 145b may at least partially radially define processing region 108b. The pumping liners 145 may be seated on a choke plate 147, which may control heat distribution from the lid stack to the cooled chamber body. A blocker plate 150 may be positioned between a lid 155 and the faceplate 140 in embodiments, and again separate blocker plates may be included to facilitate fluid distribution within each processing region. For example, blocker plate 150a may be included for distribution towards processing region 108a, and blocker plate 150b may be included for distribution towards processing region 108b.

Lid 155 may be a separate component for each processing region, or may include one or more common aspects. Lid 155 may be one of two separate lid plates of the system in some embodiments. For example, a first lid plate 158 may be seated over transfer region housing 125. The transfer region housing may define an open volume, and first lid plate 158 may include a number of apertures through the lid plate separating the overlying volume into specific processing regions. In some embodiments, such as illustrated, lid 155 may be a second lid plate, and may be a single component defining multiple apertures 160 for fluid delivery to individual processing regions. For example, lid 155 may define a first aperture 160a for fluid delivery to processing region 108a, and lid 155 may define a second aperture 160b for fluid delivery to processing region 108b. Additional apertures may be defined for additional processing regions within each section when included. In some embodiments, each quad section 109—or multi-processing-region section that may accommodate more or less than four substrates, may include one or more remote plasma units 165 for delivering plasma effluents into the processing chamber. In some embodiments individual plasma units may be incorporated for each chamber processing region, although in some embodiments fewer remote plasma units may be used. For example, as illustrated a single remote plasma unit 165 may be used for multiple chambers, such as two, three, four, or more chambers up to all chambers for a particular quad section. Piping may extend from the remote plasma unit 165 to each aperture 160 for delivery of plasma effluents for processing or cleaning in embodiments of the present technology.

In some embodiments a purge channel 170 may extend through the transfer region housing proximate or near each substrate support 130. For example, a plurality of purge channels may extend through the transfer region housing to provide fluid access for a fluidly coupled purge gas to be delivered into the transfer region. The number of purge channels may be the same or different, including more or less, than the number of substrate supports within the processing system. For example, a purge channel 170 may extend through the transfer region housing beneath each substrate support. With the two substrate supports 130 illustrated, a first purge channel 170a may extend through the housing proximate substrate support 130a, and a second purge channel 170b may extend through the housing proximate substrate support 130b. It is to be understood that any additional substrate supports may similarly have a plumbed purge channel extending through the transfer region housing to provide a purge gas into the transfer region.

When purge gas is delivered through one or more of the purge channels, it may be similarly exhausted through pumping liners 145, which may provide all exhaust paths from the processing system. Consequently, in some embodiments both the processing precursors and the purge gases may be exhausted through the pumping liners. The purge gases may flow upwards to an associated pumping liner, for example purge gas flowed through purge channel 170b may be exhausted from the processing system from pumping liner 145b.

As noted, processing system 100, or more specifically quad sections or chamber systems incorporated with processing system 100 or other processing systems, may include transfer sections positioned below the processing chamber regions illustrated. FIG. 2 shows a schematic isometric view of a transfer section of an exemplary chamber system 200 according to some embodiments of the present technology. FIG. 2 may illustrate additional aspects or variations of aspects of the transfer region 120 described above, and may include any of the components or characteristics described. The system illustrated may include a transfer region housing 205 defining a transfer region in which a number of components may be included. The transfer region may additionally be at least partially defined from above by processing chambers or processing regions fluidly coupled with the transfer region, such as processing chamber regions 108 illustrated in quad sections 109 of FIG. 1A. A sidewall of the transfer region housing may define one or more access locations 207 through which substrates may be delivered and retrieved, such as by second robotic arm 110 as discussed above. Access locations 207 may be slit valves or other sealable access positions, which include doors or other sealing mechanisms to provide a hermetic environment within transfer region housing 205 in some embodiments. Although illustrated with two such access locations 207, it is to be understood that in some embodiments only a single access location 207 may be included, as well as access locations on multiple sides of the transfer region housing. It is also to be understood that the transfer section illustrated may be sized to accommodate any substrate size, including 200 mm, 300 mm, 450 mm, or larger or smaller substrates, including substrates characterized by any number of geometries or shapes.

Within transfer region housing 205 may be a plurality of substrate supports 210 positioned about the transfer region volume. Although four substrate supports are illustrated, it is to be understood that any number of substrate supports are similarly encompassed by embodiments of the present technology. For example, greater than or about three, four, five, six, eight, or more substrate supports 210 may be accommodated in transfer regions according to embodiments of the present technology. Second robotic arm 110 may deliver a substrate to either or both of substrate supports 210a or 210b through the accesses 207. Similarly, second robotic arm 110 may retrieve substrates from these locations. Lift pins 212 may protrude from the substrate supports 210, and may allow the robot to access beneath the substrates. The lift pins may be fixed on the substrate supports, or at a location where the substrate supports may recess below, or the lift pins may additionally be raised or lowered through the substrate supports in some embodiments. Substrate supports 210 may be vertically translatable, and in some embodiments may extend up to processing chamber regions of the substrate processing systems, such as processing chamber regions 108, positioned above the transfer region housing 205.

The transfer region housing 205 may provide access 215 for alignment systems, which may include an aligner that can extend through an aperture of the transfer region housing as illustrated and may operate in conjunction with a laser, camera, or other monitoring device protruding or transmitting through an adjacent aperture, and that may determine whether a substrate being translated is properly aligned. Transfer region housing 205 may also include a transfer apparatus 220 that may be operated in a number of ways to position substrates and move substrates between the various substrate supports. In one example, transfer apparatus 220 may move substrates on substrate supports 210a and 210b to substrate supports 210c and 210d, which may allow additional substrates to be delivered into the transfer chamber. Additional transfer operations may include rotating substrates between substrate supports for additional processing in overlying processing regions.

Transfer apparatus 220 may include a central hub 225 that may include one or more shafts extending into the transfer chamber. Coupled with the shaft may be an end effector 235. End effector 235 may include a plurality of arms 237 extending radially or laterally outward from the central hub. Although illustrated with a central body from which the arms extend, the end effector may additionally include separate arms that are each coupled with the shaft or central hub in various embodiments. Any number of arms may be included in embodiments of the present technology. In some embodiments a number of arms 237 may be similar or equal to the number of substrate supports 210 included in the chamber. Hence, as illustrated, for four substrate supports, transfer apparatus 220 may include four arms extending from the end effector. The arms may be characterized by any number of shapes and profiles, such as straight profiles or arcuate profiles, as well as including any number of distal profiles including hooks, rings, forks, or other designs for supporting a substrate and/or providing access to a substrate, such as for alignment or engagement.

The end effector 235, or components or portions of the end effector, may be used to contact substrates during transfer or movement. These components as well as the end effector may be made from or include a number of materials including conductive and/or insulative materials. The materials may be coated or plated in some embodiments to withstand contact with precursors or other chemicals that may pass into the transfer chamber from an overlying processing chamber.

Additionally, the materials may be provided or selected to withstand other environmental characteristics, such as temperature. In some embodiments, the substrate supports may be operable to heat a substrate disposed on the support. The substrate supports may be configured to increase a surface or substrate temperature to temperatures greater than or about 100° C., greater than or about 200° C., greater than or about 300° C., greater than or about 400° C., greater than or about 500° C., greater than or about 600° C., greater than or about 700° C., greater than or about 800° C., or higher. Any of these temperatures may be maintained during operations, and thus components of the transfer apparatus 220 may be exposed to any of these stated or encompassed temperatures. Consequently, in some embodiments any of the materials may be selected to accommodate these temperature regimes, and may include materials such as ceramics and metals that may be characterized by relatively low coefficients of thermal expansion, or other beneficial characteristics.

Component couplings may also be adapted for operation in high temperature and/or corrosive environments. For example, where end effectors and end portions are each ceramic, the coupling may include press fittings, snap fittings, or other fittings that may not include additional materials, such as bolts, which may expand and contract with temperature, and may cause cracking in the ceramics. In some embodiments the end portions may be continuous with the end effectors, and may be monolithically formed with the end effectors. Any number of other materials may be utilized that may facilitate operation or resistance during operation, and are similarly encompassed by the present technology.

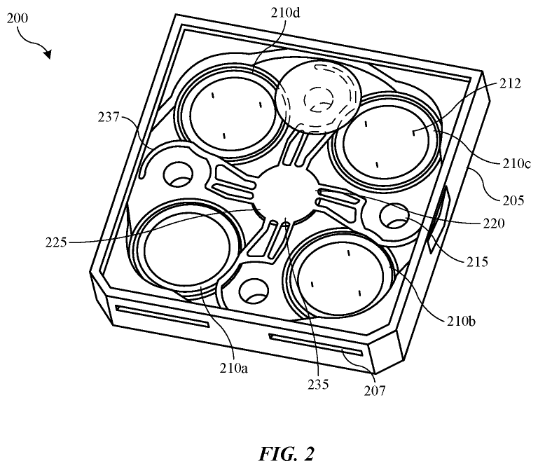

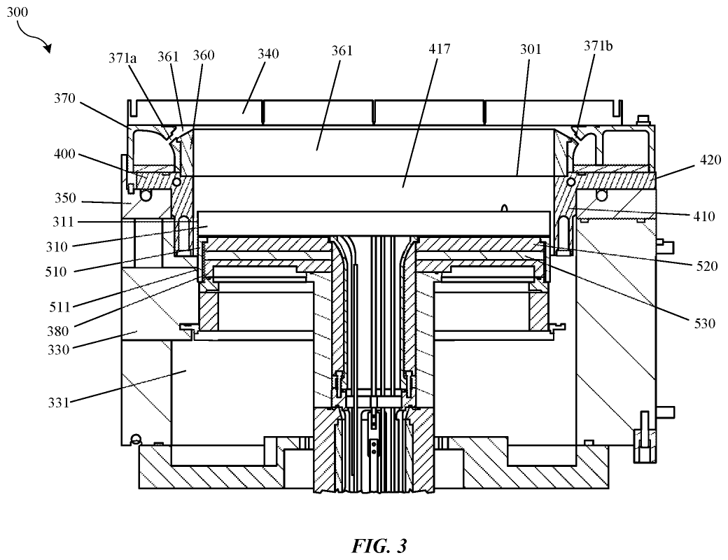

FIG. 3 shows a cross-sectional view of an exemplary substrate processing system 300 according to some embodiments of the present technology. FIG. 3 may illustrate further details relating to components in system 100, such as for choke plate 147. System 300 is understood to include any feature or aspect of system 100 discussed previously in some embodiments. The system 300 may be used to perform semiconductor processing operations including deposition of hardmask materials as previously described, as well as other deposition, removal, and cleaning operations. In particular, the substrate processing system 300 may include a transfer region housing (or chamber body) 330, outer isolator 510, top (or first) isolator 520, bottom (or second) isolator 530, pedestal 310, choke plate 400, lower lid plate 350, upper lid plate 360, faceplate 340, pumping liner 370, a ground plate 380, and/or a bellow 600 (among other components). The chamber body 330 may define a transfer region (or chamber volume) 331 therein for housing various components of the substrate processing system 300 during use. In particular, the chamber body 330 can house the pedestal 310, ground plate 380, and isolators 510,520,530 as they are vertically translated to a processing region, as discussed further below.

Pedestal or substrate support 310 may be disposed within the interior of the chamber body 330. The substrate support 310 may be vertically translatable within the chamber body 330 between the transfer region and the processing region. The substrate support 310 may include a support plate, which may include a heater, an isolator, and/or a ground plate 380. The substrate support 310 may also include a shaft that may extend through a bottom of the chamber body 330. The substrate support 310 is translatable within the chamber body 330 between a lower transfer region (illustrated here) and an upper processing region. During a processing operation, the substrate support 310 is moved upward within the chamber body 330 into a process position within the processing region. Once deposition and/or other processing operations are complete, the substrate support 310 may be lowered to a transfer position within the transfer region. The processed substrate may be removed from the substrate support 310 and a new substrate may be positioned atop the substrate support 310.

The stack of components seated on the chamber body 330 may define a processing region 301 overlying the chamber volume 331. For example, a top boundary of the processing region 301 may be defined by a bottom surface of the faceplate 340, a lower boundary of the processing region 301 may be defined by the pedestal 310, and lateral boundaries of the processing region 301 may be defined by inner surfaces of the lower lid plate 350, the upper lid plate 360, the pumping liner 370, and/or the choke plate 400. The lower lid plate 350 may be seated atop the chamber body 330 (either directly or indirectly).

The choke plate 400 may be seated on an upper surface of the lower lid plate 350. The choke plate 400 may be seated on the lower lid plate 350 on a first surface of the choke plate 400. The choke plate 400 may define a first aperture axially aligned the processing chamber and pedestal 310. The choke plate 400 may also define a second aperture axially aligned with an exhaust lumen formed in the chamber body 330 and/or pumping liner 370 that may form a portion of an exhaust channel to evacuate gases from the processing region 301. As illustrated, choke plate 400 may include a rim 410 defining the first aperture through the choke plate 400. The rim 410 may extend along a sidewall of the lower lid plate 350. In some embodiments a gap may be maintained between the rim 410 and the lid plate to control heat flow between the components. Rim 410 may extend vertically from the first surface of the choke plate 400 in a direction towards the lower lid plate 350, and may form a protrusion from the choke plate 400. The choke plate 400 may also include a flange 420 that extends laterally outward from the rim 410. For example, the flange 420 may extend outward from an outer surface of the rim 410 and may be seated atop the lower lid plate 350 in some embodiments. In a particular embodiment, the flange 420 and the rim 410 may share a single first surface such that the flange 420 is positioned at a top end of the choke plate 400, although other positions of the flange 420 relative to the rim 410 are possible. The rim 410 may include a distal end 401. The distal end 401 may be the bottom-most end of the choke plate 400 such that, when the choke plate 400 is assembled in the substrate processing system 300, the end 401 is the portion of the choke plate 400 that extends farthest into the chamber volume 331.

The upper lid plate 360 and pumping liner 370 may be seated atop the choke plate 400, such as atop the first surface of the choke plate 400. The upper lid plate 360 may have a top edge shorter than a top edge of the pumping liner 370 such that there is a vertical gap 361 between the upper lid plate 360 and the pumping liner 370. The vertical gap 361 may enable one or more gases to exhausted from the processing region 301 via one outlets 371 a,b that are defined in a surface of the pumping liner 370. Gases exhausted via the pumping liner 370 may be passed through apertures defined by the choke plate 400 and chamber body 630 that are radially outward of the processing region.

An inner surface 417 of the upper lid plate 360 and an inner surface of the choke plate 400 may be aligned flush with each other such that the inner surfaces define a substantially uniform diffusion surface. For example, the inner surfaces may have substantially the same circumference and be concentric with each other to define the smooth surface. This smooth surface allows for purge gas to flow along the surface without running into interference, thus allowing for a more uniform and consistent diffusion of purge gas to the faceplate 340. This increased uniformity and consistency, in turn, allows for a decreased flow rate for the purge gas to purge the faceplate 340 and prevent sublimation. Similarly, an outer surface 311 of the pedestal 310 and an outer surface of the outer isolator 511 may be aligned flush with each other such that the outer surface 311 and the outer surface of the outer isolator 511 define a substantially smooth and uniform diffusion surface between the pedestal 310 and the chamber walls. For example, the outer surface 311 and the outer surface of the outer isolator 511 may have substantially the same circumference and be concentric with each other to define the smooth surface. This smooth surface achieves a similar result as discussed above for the uniform surface of the inner surfaces. Therefore, the smooth surface of the inner surfaces and the smooth surface of the outer surfaces 311,511 define, between them, a portion of the processing purge flow path that has substantially no interfering protrusions to inhibit purge gas flow. The purge gas may flow between these surfaces uniformly and allow for maximal transfer of flow rate towards the faceplate 340.

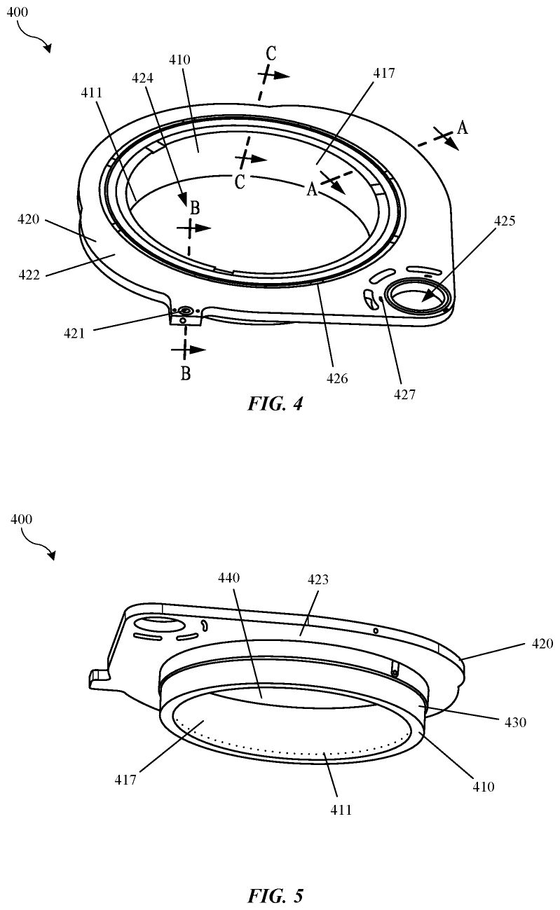

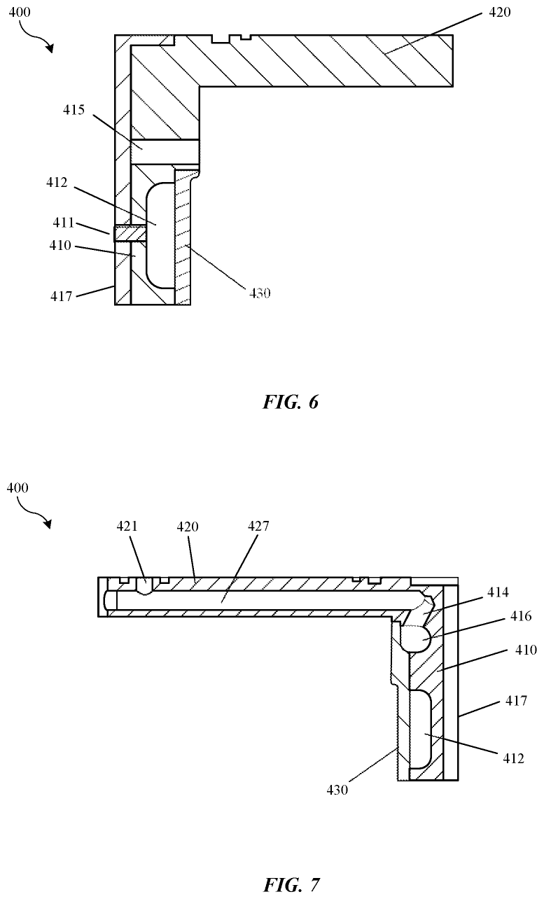

FIGS. 4-8 shows the choke plate 400. As discussed above for choke plate 147, the choke plate 400 may be used to control heat distribution to a chamber in the substrate processing system (e.g., the chamber body 330). As illustrated, choke plate 400 may be or include a thermally conductive plate defining a first aperture 424 through the plate, and a second aperture 425 through the plate. The second aperture 425 may be laterally offset on the choke plate 400 from the first aperture 424. The geometry of the choke plate 400 may be provided to accommodate the structure of the lid plate on which the choke plate 400 may be seated (such as lower lid plate 350). In a particular embodiment, an outer periphery of the choke plate 400 may be generally tear drop-shaped. For example, the outer periphery may include a small arc-shaped segment that is joined with a larger arc-shaped segment via two generally linear segments. The second aperture 425 may be coaxial with the small arc-shaped segment, while the first aperture 424 may be coaxial with the larger arc-shaped segment.

The choke plate 400 may define a first set of protrusions 426 extending from a first surface 422 of the choke plate 400. The choke plate 400 may be seated on the lid plate on protrusions 515 in some embodiments. The first set of protrusions 426 may be distributed radially about the first aperture 424 as illustrated. For example, the protrusions 426 may be distributed in a generally symmetric arrangement about the first aperture 424. The protrusions 426 may be spaced apart at regular (or substantially regular) intervals about the first aperture 424. As used herein, substantially regular intervals may be understood to mean that an angular spacing between any two adjacent protrusions may be within or about 10 degrees of an average angular spacing between adjacent protrusions of the choke plate 400, within or about 5 degrees of the average angular spacing, within or about 4 degrees of the average angular spacing, within or about 3 degrees of the average angular spacing, within or about 2 degrees of the average angular spacing, within or about 1 degree of the average angular spacing, or less.

Although eight protrusions 426 are illustrated, it is to be understood that any number of protrusions 426 may be included in embodiments of the present technology. For example, the choke plate 400 may include at least or about four protrusions 426, at least or about five protrusions 426, at least or about six protrusions 426, at least or about seven protrusions 426, at least or about eight protrusions 426, at least or about nine protrusions 426, at least or about 10 protrusions 426, at least or about 12 protrusions 426, at least or about 14 protrusions 426, or more. Each protrusion 426 may project outward from the first surface of the choke plate 400 by between or about 0.05 mm and 0.50 mm, between or about 0.10 mm and 0.40 mm, between or about 0.15 mm and 0.30 mm, or about 0.20 mm. Protrusions 426 may be arcuate segments, however a length of each protrusion 426 may be sufficiently small that each protrusion 426 may be nearly rectangular in shape. Each protrusion 426 may have a length or average length (e.g., average of a length of an inner edge and an outer edge of each protrusion 426) of between or about 5 mm and 50 mm, between or about 10 mm and 40 mm, between or about 15 mm and 30 mm, or about 20 mm. A width (e.g., a distance between an inner edge and an outer edge of each protrusion 426) of each protrusion 426 may be between or about 1 mm and 10 mm, between or about 2 mm and 9 mm, between or about 3 mm and 8 mm, or between or about 4 mm and 7 mm. Typically, each of the protrusions 426 has a same set of dimensions, although some embodiments may incorporate one or more protrusions 426 with different dimensions.

Choke plate 400 may define a number of protrusions 427 that extend from the first surface of the choke plate 400 (e.g., along flange 420), with the protrusions 427 being distributed radially about the second aperture 425 as illustrated. For example, the protrusions 427 may be distributed in a generally symmetric arrangement about the second aperture 425. The protrusions 427 may be spaced apart at regular (or substantially regular) intervals about the second aperture 425. Although three protrusions 427 are illustrated, it is to be understood that any number of protrusions 427 may be included in embodiments of the present technology. For example, the choke plate 400 may include at least or about three protrusions 427, at least or about four protrusions 427, at least or about five protrusions 427, or more. Each protrusion 427 may project outward from the first surface of the choke plate 400 by between or about 0.05 mm and 0.50 mm, between or about 0.10 mm and 0.40 mm, between or about 0.15 mm and 0.30 mm, or about 0.20 mm. Oftentimes, protrusions 427 may project outward from the first surface by a same or substantially same (e.g., within or about 10%, within or about 5%, within or about 3%, within or about 1%) distance as protrusions 426. Protrusions 427 may be arcuate segments, however a length of each protrusion 427 may be sufficiently small that each protrusion 427 may be nearly rectangular in shape. Each protrusion 427 may have a length or average length (e.g., average of a length of an inner edge and an outer edge of each protrusion 427) of between or about 5 mm and 30 mm, between or about 10 mm and 20 mm, or about 15 mm. A width (e.g., a distance between an inner edge and an outer edge of each protrusion 427) of each protrusion 427 may be between or about 1 mm and 8 mm, between or about 1.5 mm and 6 mm, or between or about 2 mm and 4 mm. Typically, each of the protrusions 427 has a same set of dimensions, although some embodiments may incorporate one or more protrusions 427 with different dimensions. The protrusions 426,427 may help provide a minimum contact area that limits contact between the choke plate 400 and a component seated atop the choke plate 400 (e.g., pumping liner 370).

While not illustrated, a lower surface of the flange 420 may include a similar set of protrusions about each of the first aperture 424 and second aperture 425. By incorporating an arrangement of the various protrusions about the first aperture 424 and second aperture 425, embodiments of the present technology may enable deformation of the choke plate 400 to be more uniform when under high vacuum loads. This even deformation may ensure that heat transfer through the choke plate 400 is uniform, and may help improve the temperature uniformity of the faceplate. Additionally, by keeping the protrusions small in size contact between the choke plate 400 and the pumping liner 370 and lower lid plate 350 is minimized, which limits heat transfer through the choke plate 400 and helps thermally isolate the pumping liner 370 and faceplate 340 from the colder, unheated lower lid plate 350.

In some embodiments, the choke plate 400 (and/or rim 410) may have a thickness (or height) from the first surface (e.g., top surface 422 of the rim 410 and flange 420) to a second surface (e.g., lower surface of rim 410) of between about 70 mm and 100 mm, between about 75 mm and 95 mm, between about 80 and 90 mm, or about 85 mm. In some embodiments, a thickness of the flange 420 may be between about 10 mm and 25 mm or between about 15 mm and 20 mm. Such dimensioning may enable the lower surface of rim 410 to protrude downward from the lower surface of the flange 420 by between about 45 mm and 90 mm, between about 50 mm and 85 mm, between about 55 mm and 80 mm, between about 60 mm and 75 mm, or between about 65 mm and 70 mm. This distance may help increase a diffusion distance of the chamber and may help reduce the amount of purge gas that must be flowed into the chamber during processing operations to keep the chamber components free of film residue.

The flange 420 includes top surface 422 and a bottom surface 423. The flange 420 may define a purging inlet 421 at the top surface 422 for receiving a purge gas therethrough. However, in other embodiments, the purging inlet may be defined through a peripheral edge of the flange 420 and/or along a bottom surface of the flange 420, as discussed further below. The rim 410 may define a plurality of purging outlets 411 that may be fluidly coupled with the purging inlet 421 to deliver a purge gas into an interior of the first aperture 424 (and processing region 301). The purging outlets 411 may be positioned in one or more rows at one or more vertical positions of the rim 410. For example, some or all of the purging outlets 411 may be positioned within an upper 25% of the rim 410, some or all of the purging outlets 411 may be positioned within an upper middle 25% of the rim 410, some or all of the purging outlets 411 may be positioned within a lower middle 25% of the rim 410, some or all of the purging outlets 411 may be positioned within an lower 25% of the rim 410, or other position about the rim 410.

In one example, there may be one-hundred and eighty purging outlets to allow for uniform distribution of gas exiting the purging outlets. However, in other embodiments, there may be more or less than one-hundred and eighty purging outlets. For example, there may be at least or about 40 purging outlets, at least or about 60 purging outlets, at least or about 80 purging outlets, at least or about 100 purging outlets, at least or about 120 purging outlets, at least or about 140 purging outlets, at least or about 160 purging outlets, at least or about 180 purging outlets, at least or about 200 purging outlets, at least or about 220 purging outlets, at least or about 240 purging outlets, or more. The purging outlets 411 may be formed at regular intervals and/or irregular intervals about the inner surface of the rim 410. Each purging outlet 411 may have a same diameter, or some or all of the purging outlets 411 may have different diameters from one another.

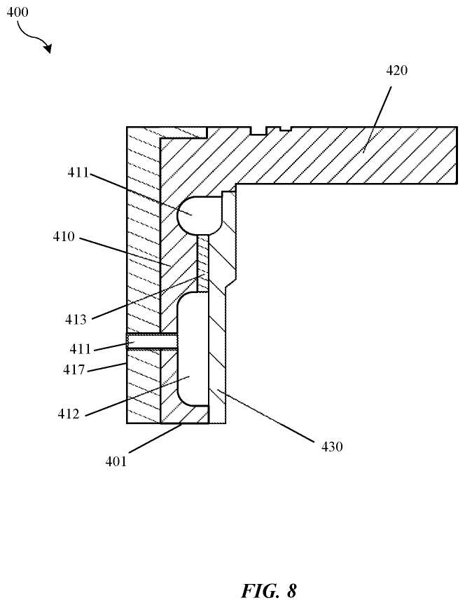

With specific reference to FIGS. 7-8, the flange 420 may define a purge channel 428 through the flange 420 in communication with, and extending from, the purging inlet 421 towards the rim 410 to form a part of the purge flow path. The purge channel 428 may be fluidly coupled with a top (or first) plenum 416, which may extend about the entire circumference of the rim 410 in some embodiments. For example, the first plenum 416 may be generally annular in shape. In other embodiments, the first plenum 416 may be generally C-shaped or arc shaped and may extend about only a portion of the periphery of the first aperture 424. Gas flowed through the purging inlet 421 and the purge channel 428 may flow into the first plenum 416 and be distributed about all or a substantial portion of the periphery of the first aperture 424. The rim 410 may define a bottom (or second) plenum 412 positioned below the first plenum 416. The second plenum 412 may extend about the entire or substantially all of the circumference of the rim 410. The second plenum 412 may be aligned with and fluidly coupled with each of the purging outlets 411, which may deliver the purge gas to the interior of the first aperture 424.

The rim 410 may define one or more baffles 413 that extend between and fluidly couple the first plenum 416 and the second plenum 412. This may enable purge gas flowing in the first plenum 416 to flow into the second plenum 412 at one or more locations about the periphery of the first aperture 424. Although FIG. 8 depicts only one baffle 413, the choke plate 400 may define any number of baffles (not shown) at different radial positions about the first aperture 424 to at least substantially distribute the purge gas about a circumference of the second plenum 412. Any number of baffles 413 may be present in choke plate 400. For example, choke plate 400 may include one or more baffles, two or more baffles, three or more baffles, four or more baffles, five or more baffles, six or more baffles, eight or more baffles, ten or more baffles, or more. Each of the baffles 413 may have a same or different diameter and/or cross-sectional area. For example, some or all of the baffles 413 may have different diameters and/or cross-sectional area to account for the proximity of the baffles to the purging inlet 421. In particular, one or more baffles closer to the purging inlet 421 may have a smaller diameter and/or cross-sectional area to account for purge gas filling up the portion of the top plenum 416 closer to the purging inlet 421 faster than the portion of the top plenum 416 further from the purging inlet 421. This difference in diameter and/or cross-sectional area allows for the purge gas to fill up the top plenum 416 and pass through the baffles 413 into the bottom plenum 412 in a substantially uniform manner. This configuration allows for the purge gas to uniformly exit the choke plate 400 to provide an even distribution of gas into the substrate processing system. The diameters of the baffles 413 may often be between about 3 mm and 15 mm, between about 4 mm and 13 mm, between about 5 mm and 11 mm, or between about 6 mm and 10 mm, although other diameters are possible in various embodiments.

In one example, there may be four total baffles 413, where the two baffles 413 closest to the purging inlet 421 may have a circumferential width of 6 mm and where the two baffles 413 farthest from the purging inlet may have a circumferential width of 10 mm. However, in other examples, there may be any number of baffles 413. Further, each of the baffles 413 may have any diameter and/or cross-sectional area to allow for uniform distribution of gas into the second plenum 412. In one alternative, there may be a single baffle 413 (such as an annular or arc-shaped baffle) extending between the plenums, with the single having a cross-sectional area along its circumference (e.g., a smaller width closer to the purging inlet 421 and a larger width farther from the purging inlet 421) to account for the position of the purging inlet 421. In a further alternative, there may be one or more baffles 413 having a substantially equal width and the rim 410 defines the top plenum 416 to have differing volumes along its circumference (e.g., a larger volume for the portions of the top plenum 416 closer to the purging inlet 421 and a smaller volume for the portions of top plenum 416 farther from the purging inlet 421) to account for the position of the purging inlet 421. In a yet further alternative, the one or more baffles 413 may have a substantially equal width and the first plenum may have a substantially equal volume along their circumference, and the rim 410 defines the bottom plenum 412 to have differing volumes along its circumference (e.g., a larger volume for the portions of the bottom plenum 412 closer to the purging inlet 421 and a smaller volume for the portions of bottom plenum 412 farther from the purging inlet 421) to account for the position of the purging inlet 421.

In some embodiments, the choke plate 400 may additionally include a closing plate 430 secured to the rim 410 through any means known in the art (e.g., welding or the like). The closing plate 430 may be used to seal off the plenums and/or baffles upon being machined and/or otherwise formed into a surface of the rim 410.

In some embodiments, a portion of the rim 410 may define a measuring hole 415 therethrough. The measuring hole 415 may be used to measure the pressure levels at the inner radius of the choke plate 400. The measuring hole 415 may be disposed between the first plenum 416 and the second plenum 412 in some embodiments.

The choke plate 400 may address problems related to faceplate sublimation faced by prior substrate processing systems. In traditional designs of substrate processing systems, purge gas is expelled from the bottom of the chamber body to clean the processing region. However, the flow rate required to purge the processing region when purge gas comes from the bottom of the chamber body was too high in prior designs.

The choke plate 400 may solve this issue by introducing the purge gas closer to the pedestal 310 and faceplate 340, which may decrease the flow rate of purge gas required to purge the processing region as the purge gas now exits the purging outlets 411. This decreased distance thus allows for the faceplate 340 to be properly purged with lower volumes of purge gas and to prevent sublimation across its face with a decreased amount of purge flow rate than what was previously required.

Additionally, when the purge gas comes from below, the purge gas may blow contaminants that are formed within the chamber body into the processing region 301. Moving the purge gas from the bottom of the chamber body to the choke plate 400 reduces the risk of such contamination as the purging outlets 411 are now much closer to the processing region 301. Moreover, by moving the purge gas introduction upward into a reactor volume of the chamber, the pressure differences between the reactor volume and shared transfer volumes in multi-chamber systems may be reduced. The temperature uniformity during hot-leveling of the pedestal 310 may also be improved.

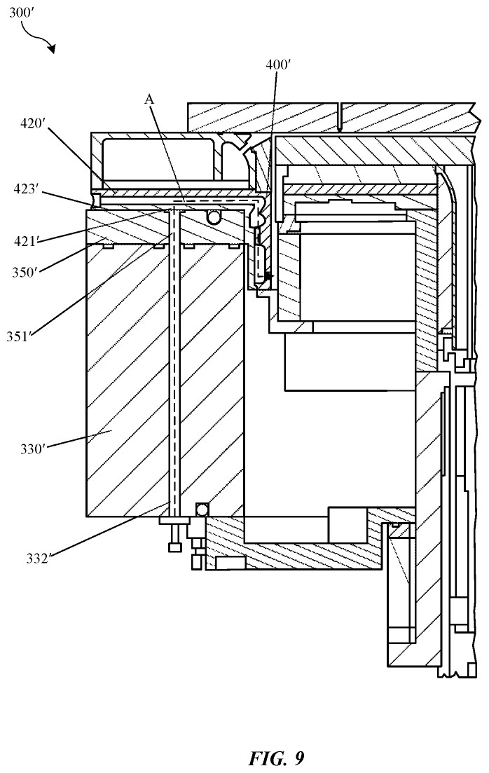

Although the choke plate 400 is depicted as having the purging inlet 421 defined along a top surface 422 of the flange 420, it may be beneficial to have the purge gas enter the choke plate 400 from the bottom surface as the purge gas source of the substrate processing system may be more preferably located below the system. FIG. 9 depicts an alternative embodiment of the choke plate where the purging inlet may be defined along a bottom surface of the lid portion of the choke plate. For example, FIG. 9 depicts a partial view of an embodiment of a substrate processing system 300′ similar to the substrate processing system 300 except as noted below. In this embodiment, features having like reference numerals as features discussed above are similar except as noted below. The flange 420′ of the choke plate 400′ may define a purging inlet 421′ along a bottom surface 423′ of the choke plate 400′. As such, the purge gas may enter the choke plate 400′ from below. The chamber body 330′ may define a chamber purging channel 332′ through the chamber body 330′ such that the source of the purge gas may enter from below the chamber body 330′. The lower lid plate 350′ defines a lid purging channel 351′ through the lower lid plate 350′ for purge gas to pass through.

In an assembled configuration, the chamber purging channel 332′, the lid purging channel 351′, and the purging inlet 421′ may all be aligned and in communication with each other such that a purge gas can flow through each of these features. For example, a purge gas may enter the chamber body 330′ and into the chamber purging channel 332′ along direction A. The purge gas may pass through the chamber purging channel 332′ and enter the choke plate 400′ through the purging inlet 421′ and eventually pass through the choke plate 400′.

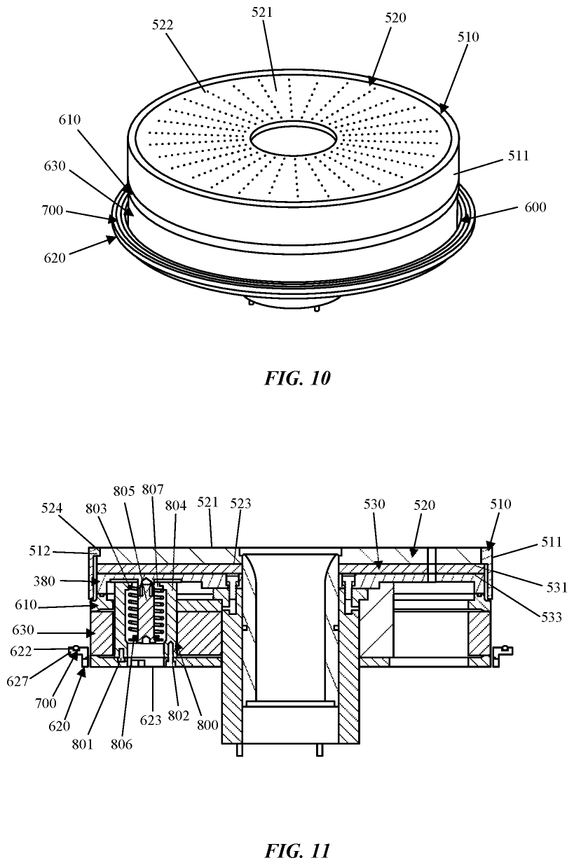

FIGS. 10-11 show a partially assembled substrate processing system with the isolators 510,520,530, the ground plate 380, the bellow 600, an RF gasket 700, and a spring mechanism 800 assembled together. The assembly of the bellow 600, RF gasket 700, and the spring mechanism 800 will be discussed further below. The isolators 520,530 may be substantially cylindrical disks. The top isolator 520 may have a top surface 521 and a bottom surface 523. The bottom isolator may have a top surface 531 and a bottom surface 533. The top isolator 520 may define one or more ledges along an outer edge of the top isolator 520 for receiving one or more components of the substrate processing system. For example, the top isolator 520 may define a ledge 524 that can receive a portion of a component (e.g., a portion of the outer isolator 510, as discussed further below) to sit atop and couple to the top isolator 520. Although not show, there may multiple ledges defined around an outer circumference of the top isolator 520 to allow for multiple portions of a component (or multiple components) to sit atop and couple to the top isolator.

The top isolator 520 may be seated on the bottom isolator 510, and the outer isolator may be seated surrounding the isolators 520,530. Having multiple isolators allows for a greater reduction in heat transfer, due to the separation between the isolators 520,530, between a heated component on the top surface 521 of the top isolator 520 (e.g., the pedestal 310) and the components beneath the bottom isolator 530 (e.g., the ground plate 380).

Isolators 520,530 may define dimples extending outward from one or more of their respective top and bottom surfaces 521,523,531,533. For example, with specific reference to FIG. 10, the top isolator 520 may define dimples 522 extending out of the top isolator 520 from the top surface 521. The top isolator 520 may additionally define dimples extending outward from the bottom surface 523, and the bottom isolator 530 may additionally define dimples extending outward from the bottom surface 533. The dimples 522 may be arranged in various patterns, such as a number of annular rings, radial lines, and/or other symmetric or asymmetric patterns. Any number of dimples 522 may be used in various embodiments. For example, a given surface may have 25 or more dimples, 50 or more dimples, 100 or more dimples, 150 or more dimples, 200 or more dimples, 250 or more dimples, 300 or more dimples, 350 or more dimples, 400 or more dimples, 450 or more dimples, 500 or more dimples, or more. These dimples may act as minimum contact areas that reduce the heat transfer from a heated component of the substrate processing system (e.g., the pedestal 310) and the components beneath the bottom isolator 530 (e.g., the ground plate 380). In alternative embodiments, there may dimples extending from all of the top and bottom surfaces of both isolators. Alternatively, there may be less than three sets of dimples extending from one of the top and bottom surfaces of the isolators.

The dimples may have a height for optimally reducing the heat transfer from the heated component to the rest of the substrate processing system (e.g., to the ground plate 380) while still providing structural support to the heated component. For example, the dimples 522 may have a 0.13 mm height, the dimples extending from the bottom surface 523 may have a 0.5 mm height, the dimples extending from the bottom surface 533 may have a 0.5 mm height. However, in other embodiments dimple heights may be different. For example, the dimples may have a height ranging from between or about 0.05 mm and 0.70 mm, between or about 0.10 mm and 0.65 mm, between or about 0.15 mm and 0.60 mm, between or about 0.2 mm and 0.55 mm, or between or about 0.25 mm and 0.5 mm. Further, the dimples may have any combination of relative heights to optimize heat transfer reduction. For example, the dimples may all have the same height. Alternatively, the dimples may all have differing heights.

The outer isolator 510 may circumferentially surround the isolators 520,530, as well as other components in the substrate processing system, such as the ground plate 380. The outer isolator may include one or more flanges that may sit on another component in the substrate processing system (e.g., atop the ledge 524 of the top isolator 520) to couple the outer isolator 510 to that component. For example, the outer isolator 510 may have a flange 512 that can rest atop that component. The outer isolator 510 may have additional flanges (e.g., three flanges) to couple the outer isolator 510 to the component. In other embodiments, there may be more or less than three flanges. A lower surface of the flange 512 may include one or more minimum contact features, such as dimples, annular protrusions, and the like that may reduce the contact area between the flange 512 and the outer isolator.

The isolators 510,520,530 may be made of a material that minimizes heat transfer. For example, one or more of the isolators 510,520,530 may be made of ceramic. In one instance, all of the isolators 510,520,530 may be made of ceramic. The ceramic material may further reduce the heat transfer between components above the isolators 510,520,530 and the components below the isolators 510,520,530. In other embodiments, the isolators may be made of other material besides ceramic that provides comparable or greater reduction in heat transfer.

The isolators 510,520,530 addresses problems related to substrate contamination from contaminants coming from the substrate processing system. For example, the ground plate 380 may be stainless steel coated with aluminum. The aluminum coating may be provided to minimize the risk of stainless steel oxidation, which is exacerbated by high temperatures (e.g., from the heat generated by the pedestal 310 above the ground plate 380 during substrate processing), and forming contaminants. However, this aluminum coating may be rated for a temperature lower than the temperatures used when processing substrates. As such, the aluminum coating may flake off and reveal the stainless steel material, leading to the ground plate 380 oxidizing and forming contaminants that have a risk of contaminating the substrates. The use of multiple isolators and minimum contact features that may help reduce the amount of heat transfer to the ground plate to better isolate the ground plate from high temperatures of the pedestal.

The isolators 510,520,530 help minimize the risk of this oxidation. In particular the isolators 520,530 reduce the heat transfer coming from the component on top of them (e.g., a heated pedestal) through the gaps defined through the isolators 520,530, the spacing between the isolators 520,530, and the material of the isolators 510,520,530. Additionally, the outer isolator 530 acts as a shield for the ground plate 380 by reducing the heat transfer to the sides of the ground plate 380. The isolators 510,520,530, therefore, individually and in combination, may minimize the risk of contamination to the substrates by sufficiently reducing the heat transfer to the ground plate 380 to prevent the aluminum coating from flaking off and exposing the stainless steel.

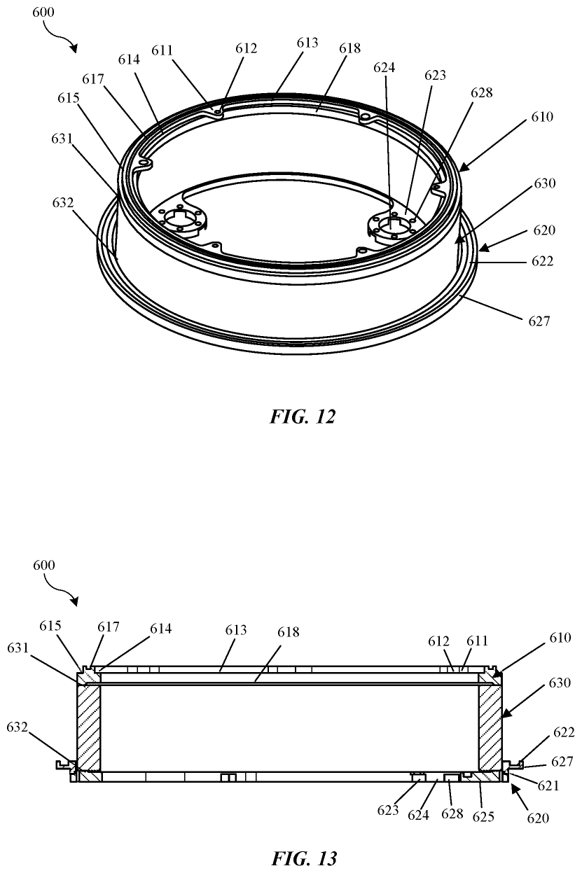

FIGS. 12-13 show the bellow 600. The bellow 600 may include a cap plate 610, a bellow plate 620, and/or a bellow body 630. The cap plate 610 may be seated on top of a top (or first) end 631 of the bellow body 630 and a bottom (or second) end 632 of the bellow body 630 may be seated on top of the bellow plate 620. The ends 631,632 of the bellow body 630 may respectively be secured to the cap plate 610 and the bellow plate 620 through welding, soldering, screwing, or other means of securement.

The cap plate 610 may be shaped to couple one or more component of a substrate processing system (e.g., the outer isolator 510 and the ground plate 380) to the bellow 600. In particular, the cap plate 610 may include a cap base 618 and a cap extension 613 vertically extending from the cap base 618. Although the cap extension 613 is depicted as extending from a central circumferential edge of the cap base 618, in other embodiments, the cap extension may extend from other positions along the cap base, such as an inner circumferential edge of the cap base. The cap extension 613 and the cap base 618 may be monolithically formed. However, in other embodiments, the cap extension 613 and the cap base 618 may be separate components that are joined together.

The cap extension 613 and the cap base 618 may define an inner (or first) notch 614 and an outer (or second) notch 615 therebetween. The notches 614,615 may be sized to receive a portion of another component of a substrate processing system. For example, where the bellow 600 is assembled in the substrate processing system 300, the outer notch 615 may receive an end of the outer isolator 510. However, in other embodiments, the cap plate may not include one or either of the notches. For example, the inner circumferential edge of the cap plate may not include the inner notch and/or the outer notch where no component is required to couple to the circumferential edges of the cap plate.

The cap extension 613 defines a cap channel 617. The cap channel 617 may be sized to receive a portion of another component of a substrate processing system (e.g., a portion of the ground plate 380). However, in other embodiments, there may be no cap channel where the component may have other means of coupling with the bellow. The cap extension 613 additionally may include a number of cap projections 611 extending toward an inner volume of the bellow 600. There may be any number of cap projections, such as three, four, five, six, or as much as may be desired to secure the bellow to another component of a substrate processing system.

The cap projections 611 may each define a cap aperture 612. The cap aperture 612 may be sized and shaped to receive a securing member (e.g., a screw). In this manner, where the cap extension 613 is assembled in the substrate processing system 300, the bellow 600 may be secured to the ground plate 380 through the cap channel 617 receiving a portion of the ground plate 380, a bottom surface of the ground plate 380 resting on a top surface of the cap projections 611, and a securement member, such a screw, received through a portion of the ground plate 380 and the cap aperture 612.

The bellow body 630 may be made of a flexible material, such as a flexible sheet of metal, that allows the length of the bellow body 630 to be compressed and extended. In this manner, the distance between the cap plate 610 and the bellow plate 620 may be changed based on the compression and extension of the bellow body 630. In particular, the length of the bellow body 630 may be determined based on a desired distance for moving a substrate within the processing region, as discussed further below. In one example, the bellow body 630 may have a compressed length of 40 mm and an extended length of 75 mm. However, in other examples, the bellow body may have a compressed length between 10 and 90 mm, and an extended length between 40 and 120 mm.

The bellow plate 620 may include a bellow base 625 and a bellow extension 621 extending outwardly from the bellow base 625. The bellow extension 621 may extend outwardly past an outer diameter of the bellow body 630. The bellow base 625 and bellow extension 621 may be monolithically formed. However, in other embodiments, the bellow base 625 and bellow extension 621 may be separate components that are joined together. The bellow base 625 includes a number of bellow projections 623 extending toward an inner volume of the bellow 600. There may be any number of bellow projections, such as three, four, five, six, or as much as may be desired to secure the bellow to another component of a substrate processing system.

The bellow projections 623 may define an inner bellow aperture 624 and a number of outer bellow apertures 628. The apertures 624,628 may be sized and shaped to couple the bellow 600 to a component of a substrate processing system, as discussed further below. Although the bellow projections 623 are depicted as defining only one inner bellow aperture 624 and six outer bellow apertures 628, in other embodiments, there may be more or less apertures as needed to secure the component to the bellow.

The bellow extension 621 may include a flange 627 extending outwardly from the bellow extension 621. The flange 627 may define a channel 622 dimensioned to receive a component of a substrate processing system. For example, the channel 622 may be dimensioned to receive a radio-frequency (RF) gasket. In other embodiments, the bellow plate may not include a flange and, instead, the channel may be defined along a top surface of the bellow extension for receipt of the component where it may not be desirable to have as large of an outer diameter.

Turning back to FIGS. 10-11, the bellow 600 is shown assembled together with the RF gasket 700 and spring mechanism 800. The RF gasket 700 may be received within the channel 622 of the flange 627. The RF gasket 700 may be secured to the flange 627 through a press-fit, welding, soldering, or the like. The RF gasket 700 may have a thickness and shape that vertically protrudes past the flange 627. In this manner, the RF gasket 700 may contact another component of a substrate processing system (e.g., the choke plate 400) as the pedestal 310 is raised to the process position. However, in other embodiments, the RF gasket may be sized and shaped such that a top surface of the RF gasket is substantially flush with a top surface of the flange.

The RF gasket 700 and at least the bellow plate 620 may be made of a conductive material, such as steel or aluminum, such that a radio frequency continuity may be formed when the RF gasket 700 contacts another component that may have a conductive material (e.g., the choke plate 400). However, in other embodiments, other portions of the bellow may be made of a conductive material, including the entirety of the bellow.

The spring mechanism 800 may include a body 804, an insulating securement mechanism 801, a conductive securement mechanism 802, a spring shaft 805, a spring 803, and a spring plate 806. The spring mechanism 800 may be secured to the bellow 600 through the securement mechanisms 801,802 received through the bellow projections 623 and that engage with the body 804. The insulating securement mechanism 801 may be a pin that assists in securing the body 804 to the bellow plate 620 while the conductive securement mechanism 802 may be a screw that does the same. However, in other embodiments, the securement mechanisms may take any form capable of securing the spring mechanism to the bellow. For example, the securing mechanisms may both be pins, both be screws, or may be any other form of securement mechanism.

The insulating securement mechanism 801 may be made of an insulating material, such as ceramic, while the conductive securement mechanism 802 may be made of a conductive material, such as steel or aluminum. In this manner, a radio frequency continuity may be formed from the RF gasket through to the conductive securement mechanism 802 but will not pass through the insulating securement mechanism 801. This may ensure that there is only one single path for the radio frequency to flow through.

The spring mechanism 800 may be secured through the spring shaft 805 to a portion of the ground plate 380 that is extending through an opening 807 defined by the body 804. In particular, a top end of the spring shaft 805 may extend through an inner volume of the bellow 600 to be engaged within an aperture of the ground plate 380.

The spring 803 and the spring plate 806 may encircle the spring shaft 805. The spring plate 806 may be secured to the spring shaft 805 adjacent a bottom end of the spring shaft 805 (e.g., through a press-fit, threaded fit, welding, solder, or the like). The spring plate 806 may have an outer diameter larger than the diameter of the opening 807 such that the spring plate 806 may not pass through the opening 807 and, instead, abuts against the body 804 when the spring plate 806 moves vertically a certain amount.

A top end of the spring 803 may be engaged to a bottom surface of the ground plate 380 (e.g., through welding, soldering, or the like) while a bottom end of the spring 803 may be engaged to a top surface of the spring plate 806 (e.g., through welding, soldering, or the like). In this manner, the spring 803 may assist in providing a spring force that limits a distance the ground plate 380 may move relative to the spring mechanism 800 (and, therefore relative to the bellow 600). The spring 803 may be a tension spring in various embodiments such that as the pedestal 310 is raised, the flange 627 and RF gasket contact a lower surface of the choke plate 400 (or other chamber component) and causes the bellow 600 to expand. The spring 803 may be elongated as the bellow 600 expands. Contact between the RF gasket and the choke plate 400 may help close an RF circuit by connecting the choke plate 400 with the pedestal 310. When the pedestal is lowered to a transfer position, the baffle is lowered and brought out of contact with the choke plate 400, which opens the radio frequency circuit. Additionally, when the pedestal 310 is lowered and the flange 627 and RF gasket are pulled away from the choke plate 400, tension in the spring 803 may help compress the bellow 600 to its unexpanded state.

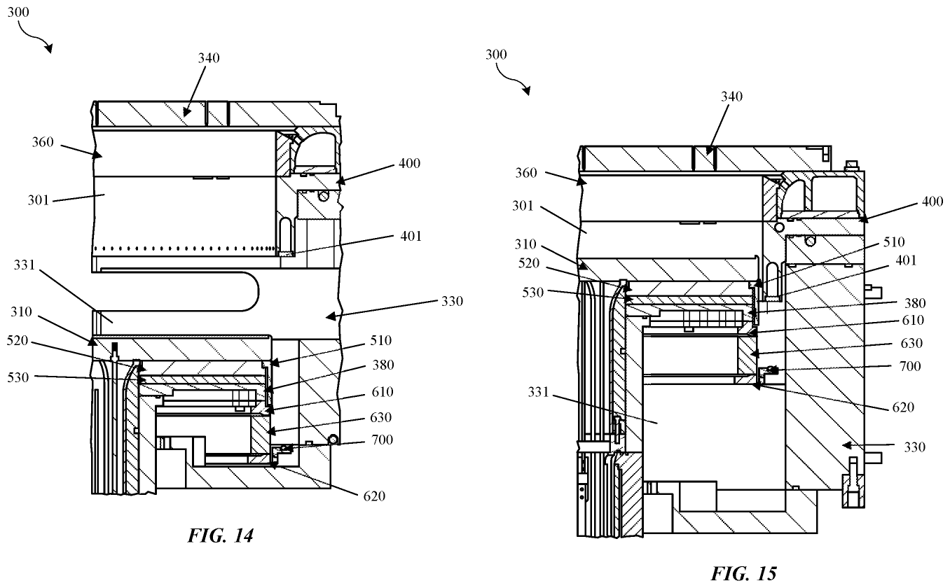

FIGS. 14-17 shows a partial view of the substrate processing system 300 as the bellow 600 moves from the transfer region 331 to, and within, the processing region 301. Turning first to FIG. 14, the bellow 600 is depicted in a rest position in the substrate processing system 300. In this position, the pedestal 310 is at its farthest from the faceplate 340.

Turning to FIG. 15, the bellow 600 is depicted as having moved up such that the pedestal 310 is leaving the chamber volume 331 and is about to enter the processing region 301. In this position, the pedestal 310 may be 90 mm away from the faceplate 340.

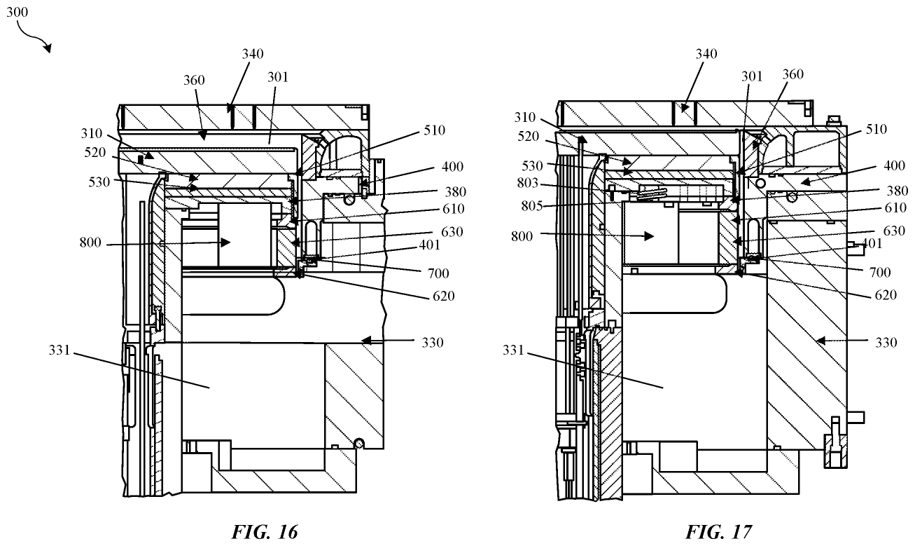

Turning to FIG. 16, the bellow 600 is depicted as having moved up such that the RF gasket within the bellow plate 620 contacts the choke plate 400 at end 401 to close an RF circuit between the pedestal 310 and the chamber walls. Specifically, the end 401 of the choke plate 400 provides a hard stop to the movement of the bellow plate 620. In this position, the pedestal 310 may be 20 mm from the faceplate 340.

Turning to FIG. 17, the bellow 600 remains in contact with the end 401 of the choke plate 400 but the bellow 600 has transitioned from a compressed position, shown in FIGS. 14-16, to an extended position. In this position, the pedestal 310 may be 5 mm away from the faceplate 340 and, where a substrate is placed on the pedestal 310, the substrate may be processed (e.g., from gasses exuded from the faceplate 340).

The bellow 600 in its compressed position in FIGS. 14-16 may be 40 mm while the bellow 600 in its extended position in FIG. 17 may be 55 mm. However, other measurements of the bellow are envisioned. For example, the bellow in its compressed position may be between 10 mm and 90 mm while the bellow in its extended position may be between 40 mm and 120 mm. The ground plate 380 may stop at the position shown in FIG. 17 based at least one of the maximum extension distance of the bellow body 630 being reached and/or the spring force.

Once the cycle of substrate processing is done, the pedestal 310 may be lowered by first lowering the bellow 600 from its extended position back to its compressed position. Then the pedestal 310 may be lowered by lowering both the bellow 600 and the pedestal 310 until the substrate processing system 300 reaches the position shown in FIG. 14. The spring force may help compress the bellow to an unexpanded state.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a plate” includes a plurality of such plates, and reference to “the aperture” includes reference to one or more apertures and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

Directional references such as “up,” “upper,” “lower,” “down,” “top,” “left,” “right,” “bottom,” among others, are not intended to be limiting and are instead intended to refer to the orientation as illustrated and described in the figure (or figures) to which the components and directions are referencing.

1. A choke plate for use in a substrate processing system, comprising:
a plate defining a first aperture through the plate and a second aperture through the plate, wherein the second aperture is laterally offset from the first aperture, the plate comprising:
a flange that defines a purging inlet; and
a rim defining a plurality of purging outlets that are fluidly coupled with the purging inlet, each of the plurality of purging outlets being fluidly coupled with the first aperture.

2. The choke plate of claim 1, wherein the purging inlet is defined along a top surface of the flange.

3. The choke plate of claim 1, wherein the purging inlet is defined along a bottom surface of the flange.

4. The choke plate of claim 1, wherein:
the rim at least partially defines a first plenum, a second plenum, and at least one baffle that extends between and fluidly couples the first and second plenum; and
the first and second plenum and baffle are in fluid communication with the purging inlet and the plurality of purging outlets.

5. The choke plate of claim 4, wherein:
the at least one baffle comprises a plurality of baffles, the plurality of baffles comprising a first baffle and a second baffle; and
the first baffle has a different cross-sectional area than the second baffle.

6. The choke plate of claim 5, wherein:
the first baffle is closer to the purging inlet than the second baffle; and
the first baffle has a smaller cross-sectional area than the second baffle.

7. The choke plate of claim 4, wherein the choke plate comprises a closing plate, the closing plate engaged to the rim to define the first and second plenums and the baffle therebetween.

8. A substrate processing system comprising:
a chamber body defining a transfer region;
a substrate support disposed within the transfer region;
a lid plate seated on the chamber body, wherein the lid plate defines an aperture through the lid plate; and
a choke plate seated on the lid plate along a first surface of the choke plate, wherein:
the choke plate defines a first aperture through the plate and a second aperture through the plate;
the second aperture is laterally offset from the first aperture;
the choke plate comprises a flange that defines a purging inlet; and
the choke plate comprises a rim defining a plurality of purging outlets that are fluidly coupled with the purging inlet, each of the plurality of purging outlets being fluidly coupled with the first aperture;
a pumping liner seated on the choke plate; and
a faceplate seated on the pumping liner.

9. The substrate processing system of claim 8, wherein:
the chamber body defines a channel in communication with the purging inlet to form a part of a processing purge flow path.

10. The substrate processing system of claim 8, further comprising a bellow coupled with an underside of the substrate support, the bellow comprises a flange having an RF gasket disposed thereon that is aligned along a vertical axis with the rim of the choke plate.

11. The substrate processing system of claim 10, wherein:
the substrate support is vertically translatable within the transfer region between a transfer position and a processing position;
in the processing position the bellow is expanded and the RF gasket contacts the rim of the choke plate to close an RF return path; and
in the transfer position the bellow is contracted and the RF gasket is vertically spaced apart from the rim of the choke plate.

12. The substrate processing system of claim 8, wherein the rim of the choke plate has a length of between about 70 mm and 100 mm.

13. A substrate processing system, comprising:
a chamber body defining a transfer region;
a substrate support disposed within the transfer region, the substrate support comprising:
a ground plate;
a first isolator seated atop the ground plate; and
a second isolator seated atop the first isolator.

14. The substrate processing system of claim 13, wherein the top isolator defines a first set of dimples extending from a surface of the first isolator and the second isolator defines a second set of dimples extending from a surface of the second isolator.

15. The substrate processing system of claim 14, wherein a height of each of the first set of dimples and the second set of dimples is equal.

16. The substrate processing system of claim 14, wherein a height of each of the first set of dimples is different than a height of the second set of dimples.

17. The substrate processing system of claim 14, wherein:
the surface of the first isolator is a top surface and the first set of dimples extends from the top surface; and
the surface of the second isolator is a bottom surface and the second set of dimples extends from the bottom surface.

18. The substrate processing system of claim 14, wherein the first isolator defines a third set of dimples extending from a bottom surface of the first isolator.

19. The substrate processing system of claim 14, further comprising an outer isolator seated on at least a portion of the first isolator.

20. The substrate processing system of claim 19, wherein:
the top isolator defines a ledge; and
the outer isolator includes a flange seated atop the ledge.
